(19) United States
(12) Patent Application Publication
(10) Pub. No.: US 2013/0269763 A1
(43) Pub. Date: Oct. 17, 2013

(54) Electrical Device

(71) Applicant: The University of Nottingham, Nottingham (GB)

(72) Inventors: C. Thomas Foxon, Nottingham (GB); Sergei Novikov, Nottingham (GB); Richard Campion, Nottingham (GB); David Cherns, Bristol (GB)

(21) Appl. No.: 13/913,083

(22) Filed: Jun. 7, 2013

Related U.S. Application Data
(63) Continuation of application No. PCT/GB2011/052446, filed on Dec. 9, 2011.

(51) Int. Cl. H01L 31/0352; H01L 31/18; H01L 31/0725

(52) U.S. Cl. CPC H01L 31/035227; H01L 31/0725; H01L 31/18
USPC 136/255; 136/262; 438/93

(57) ABSTRACT

The invention provides an electrical device, e.g. a solar cell, comprising at least one sub-cell containing a plurality of InₓGa₁₋ₓN nanocolumns or nanorods, wherein 0≦x≦1.

### CROSS-REFERENCE TO RELATED APPLICATIONS

The present application is a continuation of International Application No. PCT/GB2011/052446, filed Dec. 9, 2011, entitled “Electrical Device,” which is incorporated herein by reference as if reproduced in its entirety.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

The present invention relates to electrical devices, in particular photovoltaic or solar cells.

As is well-known, photovoltaic cells are solid state electrical devices that convert the energy of light directly into electricity by the photovoltaic effect. When the light is sunlight, the devices are commonly termed solar cells.

There are worldwide efforts to increase power generation through solar cells. Such efforts are spurred by environmental concerns, in particular the desire to reduce carbon emissions. The development of solar cells falls into two general categories. The first category comprises relatively low-cost, large area solar cells used to generate electricity locally for buildings. The second category comprises higher efficiency, typically multi-junction, solar cells that find application in concentrator systems for central power plants linked to the conventional or super-grid system. Such concentrator systems may concentrate sunlight such that it is incident on the solar cells with an intensity of from 500 to 1000 suns. Multi-junction solar cells typically contain a plurality of semiconductor material systems, each material system being selected to absorb light from a different region of the spectrum than the other(s).

When used in concentrator systems for central power plants, cell efficiency is a key issue. Solar cells with high efficiencies (greater than 30%) are being developed for concentrated solar power applications. These high efficiency cells may be single crystal multi-junction or tandem cells consisting of single solar cells based on different semiconductor systems (e.g. InGaP, GaAs and Ge as produced by Spectrolab, Inc.) which are joined by tunnel junctions. Such cells are relatively costly to produce due to the epitaxy and processing costs involved in a composite cell with three different materials systems. In addition, having two reverse biased tunnel junctions joining different material systems reduces the open circuit voltage (V_{OC}), limiting performance.

One known multi-junction solar cell has an InGaP top sub-cell which is lattice matched to a GaAs sub-cell, which in turn is lattice matched to a Ge bottom sub-cell. Each cell absorbs a different part of the spectrum: InGaP has a direct band gap of 1.8 eV, GaAs has a direct band gap of 1.4 eV and Ge has a direct band gap of 0.7 eV. This known cell has a conversion efficiency at 500 suns of around 40%. The next generation of this type of solar cell is forecast to have slightly higher conversion efficiencies.

However, as noted above, this type of multi-junction cell can be costly to produce, e.g. due to epitaxy and processing costs involved in a composite cell with three or more different materials systems. In addition, the two (in the case of a composite cell comprising three different materials systems) reverse biased junctions in different material systems reduce V_{OC}, limiting performance.

Epitaxial InGaN layers are of great interest for high efficiency solar cells, but currently suffer from materials-related problems.

It is known that nitride semiconductor layers typically have high densities of defects, e.g. dislocations, arising from lattice mismatch with the substrates on which they are grown. For instance, there is a lattice mismatch of −16.1% when an epitaxial layer of GaN is grown on a (0001) sapphire substrate. This results in high density of threading dislocations, typically up to 10⁹ to 10¹⁰ cm⁻². Dislocations will trap charge carriers (electrons or holes), leading to recombination. Thus, in a solar cell, where it is necessary to extract the carriers in order to produce a current, such a high dislocation density will be bad for overall cell performance.

In principle, InₓGa₁₋ₓN, which has a direct band gap of from ˜0.7 eV (x=1) to 3.4 eV (x=0) spanning almost the entire visible spectrum, could be used to produce a high efficiency multi-junction solar cell in a single materials system. However, as with GaN, InGaN thin films grown on practical substrates such as (0001) sapphire or (111) Si, have high densities of threading dislocations, and high lattice strains. This in turn may cause misfit dislocations and possibly phase separation problems. Such defects lead to increased carrier recombination and hence reduced solar cell efficiencies.

### DETAILED DESCRIPTION

It is a non-exclusive object of the present invention to provide a solar cell which is easier and/or cheaper to make and/or more efficient than known solar cells.

A first aspect of the invention provides a photovoltaic cell or a solar cell comprising at least one sub-cell containing a plurality of InₓGa₁₋ₓN nanocolumns or nanorods, wherein 0≦x≦1.

In this application, “solar cell” refers to a fully-assembled photovoltaic device. A given solar cell or photovoltaic cell may contain one or more “sub-cells”, each sub-cell containing a photovoltaic semiconductor material. Hence, for example, a multi-junction solar cell (MJSC) may contain a plurality of sub-cells.

Advantageously, each nanocolumn or nanorod may be substantially defect free. Typically, each nanocolumn or nanorod may contain no more than one defect.

The nanocolumns or nanorods may be able to expand or contract laterally, in order to elastically accommodate any strain caused by lattice mismatch without creating defects, because, typically, the nanocolumns or nanorods may be discrete, i.e. spaced apart from one another. Typically, the nanocolumns or nanorods may be substantially parallel to one another.

Further advantages of the invention and of the solar cells according to the invention in particular will become apparent to persons skilled in the art upon reading through this patent application.

In an embodiment, x may be 0.1 or more, preferably 0.4 or more.

In an embodiment, the solar cell may comprise a plurality of sub-cells containing the nanocolumns or nanorods, a tunnel junction, e.g. a reverse biased tunnel junction, being present between each pair of adjacent sub-cells.

In an embodiment, x may take a different value for the nanocolumns in one or more of the sub-cells from the value x takes in the other sub-cells.

In an embodiment, x may take a different value for the nanocolumns in each sub-cell.

In an embodiment, the solar cell may comprise a first sub-cell and a second sub-cell, a tunnel junction being present between the first sub-cell and the second sub-cell, wherein x for the nanocolumns in the first sub-cell is different from x for the nanocolumns in the second sub-cell.

For the nanocolumns in the first sub-cell, x may be no less than 0.4 and/or no more than 0.5. For the nanocolumns in the second sub-cell, x may be no less than 0.65 and/or no more than 0.8.

The solar cell may further comprise a third sub-cell, a tunnel junction being present between the second sub-cell and the third sub-cell, wherein x for the nanocolumns is different in each of the first, second and third sub-cells.

In an embodiment, one or more of the tunnel junctions may be provided within a continuous layer.

In an embodiment, one or more of the tunnel junctions may be provided within the nanocolumns or nanorods.

Advantageously, at least some of the nanocolumns or nanorods may vary in composition along their length. For instance, a nanocolumn may have a first portion in which x takes a first value, a second portion in which x takes a second value, a third portion in which x takes a third value and so on, with adjacent portions being separated by tunnel junctions formed by appropriate doping of the nanocolumn. A particular advantage of this arrangement is that the tunnel junctions may be substantially defect free.

Preferably, at least some of the nanocolumns may have a relatively high In content, e.g. x may be 0.6 or more, preferably 0.7 or more.

In an embodiment, the nanocolumns or nanorods may have a diameter of at least 5 nm, preferably at least 20 nm, more preferably at least 50 nm. The nanocolumns may have a diameter of no more than 500 nm, preferably no more than 200 nm, more preferably no more than 100 nm.

In an embodiment the spacing from any given nanocolumn or nanorod to its nearest neighbour(s) may be at least 5 nm and no more than 500 nm. For instance, the spacing from any given nanocolumn to its nearest neighbour(s) may be from 5 nm to 100 nm.

In an embodiment, the nanocolumns or nanorods may have a length of from 50 nm to 1000 nm, e.g. from 100 nm to 1000 nm.

In an embodiment, the sub-cell(s) may be located between a precursor layer and an overlayer. The precursor layer and/or the overlayer may be a continuous epilayer.

In an embodiment, the solar cell may comprise electrical contacts. One or more wires may be connected to each electrical contact. Conventional methods of depositing suitable contacts will be known to persons skilled in the art.

The solar cell may be around 5 mm×5 mm or around 10 mm×10 mm in horizontal cross section.

A second aspect of the invention provides a method of manufacture of an electrical device, e.g. a photovoltaic cell or a solar cell, comprising: growing a precursor layer on a substrate; and growing a plurality of InₓGa₁₋ₓN nanocolumns or nanorods on the precursor layer, wherein 0≦x≦1.

In an embodiment, the nanocolumns or nanorods may be grown by molecular beam epitaxy, preferably plasma assisted molecular beam epitaxy (PA-MBE).

The substrate may be any suitable substrate. For instance, the substrate may comprise sapphire, e.g. (0001) sapphire with a thin AlN buffer layer deposited thereon, or silicon, e.g. (111) silicon.

The precursor layer may be a continuous epitaxial layer grown on the substrate. The precursor layer may comprise GaN or InₓGa₁₋ₓN. The precursor layer may be doped p-type or n-type.

During nanocolumn growth, the substrate and precursor layer may be oriented in any way, e.g. substantially vertically or substantially horizontally. In an embodiment, the substrate and precursor layer may be rotatable. It has been found that rotating the substrate and precursor layer can lead to good nanocolumn growth.

In order to achieve nanocolumn growth by PA-MBE, PA-MBE should generally be carried out at relatively high temperatures in N-rich conditions. Typically, rotating the substrate and precursor layer may also lead to good nanocolumn growth.

In an embodiment, the substrate may be rotated at from 10 to 100 rpm, preferably from 10 to 50 rpm, more preferably 10 to 30 rpm. For instance, the substrate may be rotated at around 20 rpm.

The substrate may be 2 to 3 inches (5 to 7 cm) in diameter.

The conditions for nanocolumn growth should be selected such that the vertical growth rate comfortably exceeds the lateral growth rate. Preferably, the ratio of vertical growth rate to lateral growth rate may be at least 4:1, more preferably at least 6:1.

A third aspect of the invention provides a method of manufacture of an electrical device, e.g. a solar cell, comprising: growing a precursor layer on a substrate; growing a plurality of InₓGa₁₋ₓN nanocolumns or nanorods on the precursor layer, wherein 0≦x≦1, with a first composition for a first period of time; doping the nanocolumns or nanorods to form a tunnel junction; and growing the nanocolumns, with a second composition for a second period of time.

The method steps may be repeated as many times as are necessary to create the desired overall solar cell structure.

When doping the nanocolumns or nanorods to form the tunnel junction(s), optionally, the nanocolumns or nanorods may be grown laterally so as to form a continuous layer.

Photovoltaic or solar cells according to the present invention may be especially suitable for use in concentrated solar power applications.

A fourth aspect of the invention provides a solar panel comprising a plurality of solar cells, at least one of which is a solar cell according to the first aspect of the invention.

A solar panel may comprise any number of solar cells according to the first aspect of the invention, depending upon how large a panel is required for a given application.

A fifth aspect of the invention provides a solar concentrator comprising at least one solar cell according to the first aspect of the invention and/or at least one solar panel according to the fourth aspect of the invention. The solar concentrator may concentrate sunlight to an intensity of from 100 to 5000 suns, e.g. from 500 to 1000 suns.

A sixth aspect of the invention provides a power plant comprising a solar cell according to the first aspect of the invention and/or a solar panel according to the fourth aspect of the invention and/or a solar concentrator according to the fifth aspect of the invention.

A seventh aspect of the invention provides the use of a solar cell according to the first aspect of the invention and/or a solar panel according to the fourth aspect of the invention and/or a solar concentrator according to the fifth aspect of the invention and/or a power plant according to the sixth aspect of the invention to produce electricity.

An eighth aspect of the invention provides a method of generating electricity comprising: exposing a solar cell according to the first aspect of the invention to sunlight, preferably via a solar concentrator, thereby generating an electric current; and transmitting the electric current along a transmission line, e.g. a wire, to a location remote from the solar cell.

The solar cell and/or the solar concentrator may be part of a power plant.

The transmission of the electric current may be done via a conventional or super-grid system.

The location may be a power point in a domestic property, a commercial property, an industrial establishment, a public amenity or a public space.

In accordance with the invention, substantially defect-free InₓGa₁₋ₓN nanocolumns or nanorods may be grown by MBE under N-rich conditions with x up to 0.7 or more on GaN precursor layers on (0001) sapphire or other substrates, e.g. (111) silicon.

Subsequently, under lateral growth conditions (In/Ga-rich conditions), a continuous layer may be grown on top of the nanocolumns or nanorods. This may form the basis of a single solar cell. The precursor layer may be doped p-type (e.g. with Mg) or n-type (e.g. with Si) and the overlayer may be doped n-type (e.g. with Si) or p-type (e.g. with Mg). Typically, continuous InₓGa₁₋ₓN layers produced by lateral growth of nanocolumns or nanorods may have much lower defect densities than continuous epilayers, e.g. around 10⁷ to 10⁸ cm⁻², as opposed to from 10⁹ to 10¹⁰ cm⁻².

Advantageously, the invention also provides for the growth of multi-junction solar cells, e.g. two, three or four junction solar cells, including InGaN/GaN/InGaN reverse biased tunnel junctions.

Doping of continuous layer regions and addition of contacts to complete a working cell may be possible using standard processing means.

The invention may provide a single solar cell consisting of a p-i-n structure in which an “absorber layer” (a first sub-cell) of InₓGa₁₋ₓN nanorods is sandwiched between a p-doped GaN precursor layer and an n-doped InₓGa₁₋ₓN layer. This structure may be interfaced to a second sub-cell via a reverse biased tunnel junction.

The nanorod or nanocolumn devices according to the invention have several key advantages over devices based on continuous layers, e.g. continuous epilayers. First, the nanorods are usually perfect single crystals, free of threading defects, and remain free of defects as they grow laterally until coalescence. Threading defects, principally low angle grain boundaries, may be created at coalescence, but the overall density of such defects is significantly reduced over continuous layers (down to 10⁸ cm⁻²).

Secondly, the nanorods are “compliant structures” and have the right geometry such that misfit stresses can be eliminated by lateral relaxation. This may enable InGaN nanorods with high In content to be grown pseudomorphically on a GaN base, particularly where the composition change is graded. Misfit dislocations and the layer stresses which are believed to lead to phase separation may therefore be avoided. This is not possible with continuous epilayers as there is a 7% mismatch between GaN and InN. Stress relaxation in nanorods also means that the composition can be subsequently reversed to give InₓGa₁₋ₓN overlayers with low x (or x=0). This provides the crucial flexibility in doping needed to integrate sub-cells into a multijunction device. For instance, the lattice mismatch between InₓGa₁₋ₓN material where x=0.8 and InₓGa₁₋ₓN material where x=0.6, which can be accommodated by nanocolumns without generating misfit dislocations.

There is also good evidence that high crystal quality InGaN nanorods can be grown by MBE for all compositions up to pure InN. If threading dislocations are generated, e.g. in a misfit dislocation source, it has been observed that they are eliminated on the nanorod sides; the driving force is assumed to be relaxation of strain energy. Our work shows that threading defects can be generated in nanorods and propagate where they provide a top surface growth step. However, when practicing the invention the probability of such defect generation is generally low (less than 5-10%), depending on the growth conditions and perhaps the surface morphology. Stress relaxation in nanorods also means that the composition can be reversed to give InGaN with low x, thus enabling the p-type layers (needed in the two-junction device) to be in low x material. This is important for two reasons (a) p-type doping of high x material is difficult owing to the conduction band edge being below the Fermi level, (b) for MJSCs, it is necessary to interface a lower region with high x (low band gap) to an upper layer with lower x (high band gap).

The invention offers the potential advantage of using the optimum combination of band gaps for improved overall efficiency, combined with lower epitaxy and processing costs, and without the use of toxic materials. For instance, the manufacturing process may be maskless and may not require the use of any etching chemicals (or at least only relatively small amounts).

InₓGa₁₋ₓN also has intrinsic properties which are advantageous for solar cells, including a high optical absorption of around 2×10⁵ cm⁻¹, giving greater than 90% absorption in 200 nm, compared with 10 microns or greater for Si, and high carrier mobility and high drift velocity which may reduce carrier recombination rates. Moreover, the high piezoelectric and spontaneous electric fields present in GaN heterostructures can be used to enhance the tunnelling through the reverse biased junctions.

For x greater than 0.43, theory suggests that the nanorod or nanocolumn surfaces may show electron accumulation, although the depth of the electron accumulation layer should be only 2-3 nm. This suggests that electrons and holes may become spatially separated, reducing the probability of electron-hole recombination. This is a potential advantage for solar cells.

In order that the invention may be well understood, it will now be described, by way of example only, with reference to the accompanying drawings, in which:

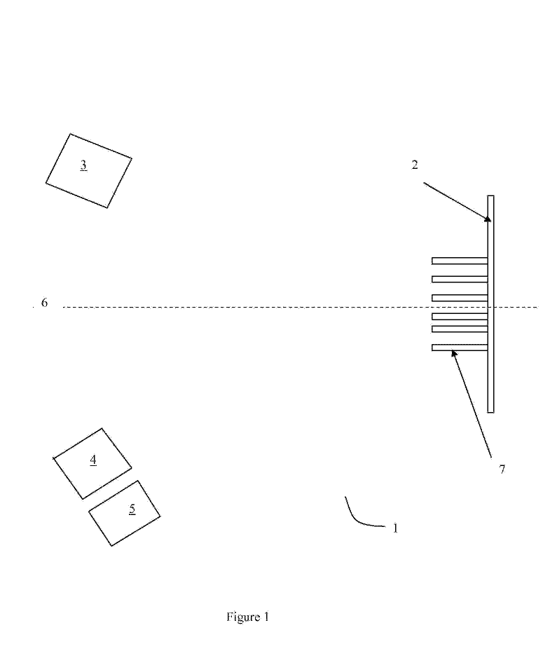

FIG. 1 shows schematically an apparatus for growing InxGa1-xN nanocolumns for solar cells according to the invention;

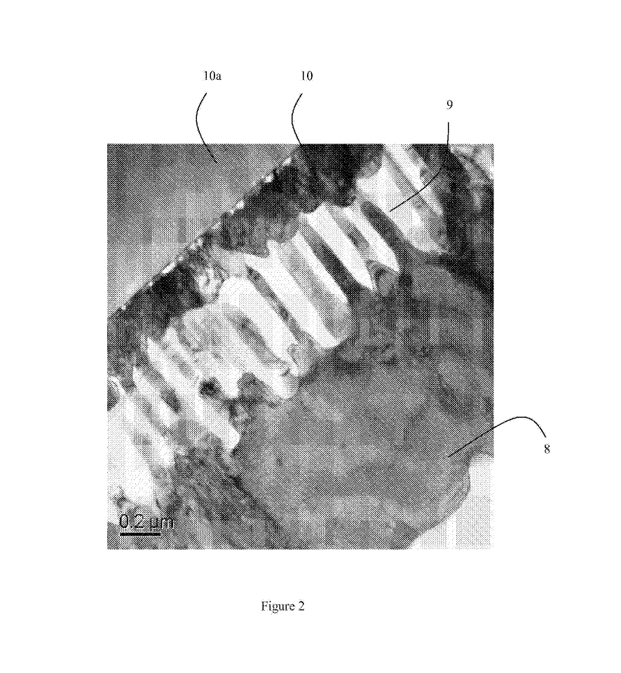

FIG. 2 is a transmission electron microscopy (TEM) image showing GaN nanocolumns grown on a substrate;

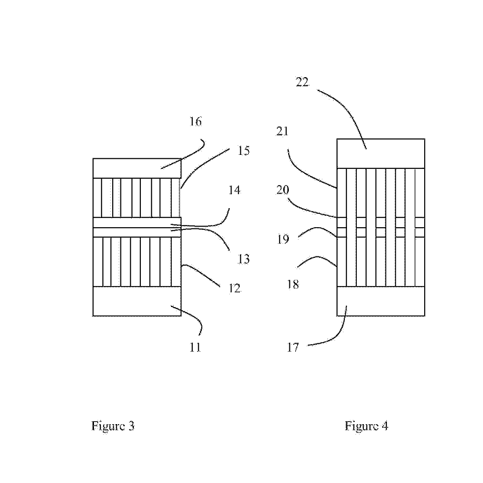

FIG. 3 is a schematic drawing of a first embodiment of a multi-junction solar cell according to the invention; and

FIG. 4 is a schematic drawing of a second embodiment of a multi-junction solar cell according to the invention.

FIG. 1 shows an apparatus for growing nanocolumns or nanorods by plasma assisted molecular beam epitaxy (PA-MBE). As shown in FIG. 1, the apparatus comprises an evacuated chamber 1. Within the chamber 1, there is a substrate 2, on which nanocolumns can be grown. The substrate 2 is held in a substantially vertical orientation and is rotatable about an axis 6 normal to the substrate 2. The axis 6 is indicated by a dashed line. Any suitable material may be used as a substrate. For instance, the substrate 2 may comprise sapphire or silicon. A precursor layer, e.g. an epitaxial layer, may be grown on the substrate 2, prior to nanocolumn or nanorod growth.

The apparatus also includes a source of atomic nitrogen 3, a source of atomic gallium 4 and a source of atomic indium 5. The sources 3, 4, 5 are situated off the axis 6: the N source 3 is located above the axis 6, while the Ga source 4 and In source 5 are located below the axis 6. Therefore, the flux from the N source 3 arrives at the substrate from a different direction from the flux from the Ga source 4 or the In source 5. The sources 3, 4, 5 may be located from 20° to 50°, typically from 30° to 40°, from the axis 6.

In order to achieve good nanocolumn growth, PA-MBE should be carried out in an N-rich environment, at a relatively high temperature, and whilst rotating the sample. By N-rich is meant that there is an atomic excess of N. In order to change the growth mode from nanocolumn growth to growth of a continuous overlayer, the conditions should be changed such that they are Ga- and In-rich, rather than N-rich.

A Varian GEN-II system is an example of a suitable PA-MBE system.

Other PA-MBE set-ups and systems may also be suitable. For instance, the substrate may be oriented substantially horizontally, with the sources located above or below the substrate.

We have grown GaN nanocolumns by PA-MBE under strongly N-rich conditions at high temperature in a Varian GEN-II system. The GaN nanocolumns were grown on uncoated sapphire substrates using a thin AlN buffer layer (approximately 5 nm thick). The AlN buffer layer promotes nanocolumn growth. The Ga flux beam equivalent pressure was around 7×10⁸ Ton. Active (atomic) nitrogen was produced by a HD25 RF plasma source operating at 450 W with a nitrogen flow rate of around 2.5 sccm. The substrate was rotated at a speed of around 20 rpm.

It is envisaged that the same or similar conditions could be used to grow InₓGa₁₋ₓN nanocolumns or nanorods, where x≠0.

FIG. 2 is a TEM image which illustrates nanocolumn growth. FIG. 2 shows GaN nanocolumns 9 grown by molecular beam epitaxy on a (0001) sapphire substrate 10a following the deposition of a thin AlN precursor layer. The sapphire substrate 10a is in the top left corner of the image. Initially, GaN is grown under strongly N-rich conditions. This leads to a complex morphology, whereby defect-free Ga-polar nanocolumns 9 emerge from an N-polar intermediate layer 10. Following a second stage of growth under more Ga-rich conditions, lateral growth leads to a continuous Ga-polar overlayer 8. By Ga-polar is meant that the Ga—N bond is aligned parallel to the growth direction. By N-polar is meant that the Ga—N bond is aligned anti-parallel to the growth direction.

The GaN nanocolumns 9 and overlayer 8 shown in FIG. 2 could equally be made of InₓGa₁₋ₓN, wherein 0≦x≦1.

A single solar cell according to the invention could comprise InₓGa₁₋ₓN nanocolumns or nanorods with high In content grown pseudomorphically on a GaN precursor layer. High In contents may be desired in order to achieve higher cell efficiency. For a single solar cell, theoretical studies predict an optimum efficiency of 20.3% for an ideal single solar cell, when x=0.65 (1.31 eV band gap).

For a two-junction cell, i.e. a solar cell comprising two sub-cells, theory suggests that a maximum efficiency of around 32% could be achieved for a solar cell, in which x=0.48 (1.72 eV band gap) for the nanocolumns in a first sub-cell, and x=0.73 (1.12 eV band gap) for the nanocolumns in a second sub-cell.

FIG. 3 shows schematically an embodiment of a multi-junction solar cell (MJSC) according to the invention. The MJSC in FIG. 3 comprises a continuous epitaxial GaN precursor layer 11. The precursor layer 11 is doped p-type. A lower sub-cell 12 contains InₓGa₁₋ₓN (x=0.48) manocolumns (only five are shown for clarity). The nanocolumns have been grown upwardly from the precursor layer 11. The nanocolumns have a diameter of around 50 nm and are spaced apart by around 50 nm. The nanocolumns may be around 500 nm in length. A reverse-biased tunnel junction is formed above the lower sub-cell 12 by an n-doped InₓGa₁₋ₓN layer 13 and a p-doped InₓGa₁₋ₓN layer 14, both of which are formed by lateral growth of the nanocolumns. An upper sub-cell 15 contains InₓGa₁₋ₓN (x=0.73) nanocolumns (only five are shown for clarity). The nanocolumns within the upper sub-cell 15 and the lower sub-cell 12 are similarly sized and spaced apart. Finally, a top layer 16 is located across the top of the nanocolumns in the upper sub-cell 15. The top layer 16 comprises a layer GaN, which is doped n-type. The top layer 16 is grown via lateral growth of the nanocolumns.

FIG. 4 shows schematically another embodiment of an MJSC according to the invention. The compositions of the materials in each layer are the same as in FIG. 3. Hence, the MJSC in FIG. 4 comprises from bottom to top, a precursor layer 17, a lower sub-cell containing nanocolumns 18, a reverse biased tunnel junction comprising an doped n-type layer 19 and a doped p-type layer 20, an upper sub-cell containing nanocolumns 21 and an overlayer 22. In FIG. 4, unlike in FIG. 3, in each nanocolumn the reverse biased tunnel junction is made up of two sections of a nanocolumn. Thus there is no switch to lateral growth conditions and, it will be appreciated each nanocolumn or nanorod extends uninterrupted from the precursor layer to the overlayer. Accordingly, the defect density in the reverse biased tunnel junction may be significantly reduced.

In the solar cell designs shown in FIG. 3, the tunnel junction is such that tunnelling is assisted by high electric fields which are a distinctive feature of nitrides. In FIG. 4 the tunnel junctions are included within the nanorods themselves, thus avoiding defects in this region of the device, simplifying the growth further and reducing the overall device cost.

The two cells are joined by a reverse biased tunnel junction. Conventionally, this is achieved by highly doping adjacent p- and n-regions such that the depletion width is sufficiently narrow for electrons to tunnel from the valence band on the p-doped side into the conduction band in the n-doped region. In GaN alloys, this is difficult to achieve through doping alone, but can be aided by using high piezoelectric and spontaneous fields (up to several MV cm−1) present at heterostructure interfaces. This can be achieved by the insertion of a layer of AlN a few nanometres thick between p- and n-doped regions of GaN. Although this arrangement may be possible in our proposed device, e.g. as shown in FIG. 4, an alternative may be to include an InGaN/GaN/InGaN tunnel junction. As well as reducing the lattice mismatch between the lower and upper cells, this should reduce the wavefunction attenuation as the potential step in GaN is lower than in AlN, and thus increase the tunnelling current for the same barrier thickness.

The threading defect density in the overlayer may be around two orders of magnitude less than in the precursor layer (down to 10⁸ cm⁻²).

In the case where x=1 and the substrate is p-type Si, a p-n junction between the Si and InN nanocolumns or nanorods (which are n-type) is formed. This may in itself be the basis of an electrical device. Accordingly, another aspect of the invention provides an electrical device having a p-n junction between a p-type Si layer and InN nanocolumns or nanorods. The p-type Si layer may have been a substrate on which the InN nanocolumns or nanorods were grown, e.g. by MBE, more particularly by PA-MBE.

What is claimed is:

1. An apparatus comprising:
a solar cell comprising:
a sub-cell comprising a plurality of InₓGa₁₋ₓN nanocolumns, wherein 0≦x≦1.

2. The apparatus of claim 1, wherein x≧0.1.

3. The apparatus of claim 1, wherein x≧0.4.

4. The apparatus of claim 1, further comprising:
a plurality of the sub-cells; and
a tunnel junction located between two adjacent sub-cells.

5. The apparatus of claim 4, wherein the sub-cells comprise a first sub-cell and a second sub-cell, wherein the tunnel junction is positioned between the first sub-cell and the second sub-cell, and wherein x for the nanocolumns in the first sub-cell is numerically different than x for the nanocolumns in the second sub-cell.

6. The apparatus of claim 5, further comprising a third sub-cell and a second tunnel junction positioned between the second sub-cell and the third sub-cell, wherein x for the nanocolumns in the third sub-cell is numerically different than x for the nanocolumns in both the first sub-cell and the second sub-cell.

7. The apparatus of claim 5, wherein 0.4≦x≦0.5 for the nanocolumns in the first sub-cell, and wherein 0.65≦x≦0.8 for the nanocolumns in the second sub-cell.

8. The apparatus of claim 4, wherein one of the tunnel junctions is present within a continuous layer.

9. The apparatus of claim 1, wherein the apparatus is a solar panel.

10. The apparatus of claim 1, wherein the apparatus is a solar concentrator.

11. The apparatus of claim 1, wherein the apparatus is a power plant.

12. A method of manufacturing an electrical device comprising:
growing a precursor layer on a substrate; and
growing a plurality of InₓGa₁₋ₓN nanocolumns, a plurality of InₓGa₁₋ₓN nanorods, or combinations thereof on the precursor layer, wherein 0≦x≦1.

13. The method of claim 12, wherein the nanocolumns or the nanorods are grown by molecular beam epitaxy, wherein the precursor layer comprises a continuous epitaxial layer grown on the substrate, and wherein the method further comprises rotating the substrate and precursor layer during nanocolumn growth.

14. The method of claim 13, wherein the nanocolumns or the nanorods are grown by plasma assisted molecular beam epitaxy (PA-MBE).

15. The method of claim 12, wherein conditions for nanocolumn growth are selected such that a ratio of vertical growth rate to lateral growth rate is at least 4:1.

16. The method of claim 12, further comprising doping the nanocolumns to form a tunnel junction.

17. A method of manufacturing an electrical device comprising:
growing a precursor layer on a substrate;
growing a plurality of InₓGa₁₋ₓN nanocolumns, a plurality of InₓGa₁₋ₓN nanorods, or combinations thereof on the precursor layer with a first composition for a first period of time, wherein 0≦x≦1;
doping the nanocolumns or nanorods to form a first tunnel junction; and
growing the nanocolumns, with a second composition for a second period of time.

18. The method of claim 17, further comprising doping the nanocolumns or the nanorods at the end of the second period of time to form a second tunnel junction.

19. The method of claim 17, wherein doping the nanocolumns or the nanorods to form the tunnel junction comprises growing the nanocolumns or the nanorods laterally to form a continuous layer.

20. A method of generating electricity comprising:
exposing a solar cell comprising a sub-cell comprising a plurality of InₓGa₁₋ₓN nanocolumns to sunlight to generate an electric current, wherein 0≦x≦1; and
transmitting the electric current along a transmission line to a remote location.
